(19) United States
(12) Patent Application Publication
(10) Pub. No.: US 2018/0226595 A1
(43) Pub. Date: Aug. 9, 2018

(54) SILICON-BASED LARGE-SIZED OLED IMAGE TRANSCEIVING DEVICE AND MANUFACTURING METHOD

(71) Applicant: SHENZHEN DIANBOND TECHNOLOGY CO., LTD., Shenzhen (CN)

(72) Inventor: Ping LIU, Shenzhen (CN)

(21) Appl. No.: 15/948,517

(22) Filed: Apr. 9, 2018

Related U.S. Application Data
(63) Continuation of application No. PCT/CN2015/095501, filed on Nov. 25, 2015.

(30) Foreign Application Priority Data
Oct. 9, 2015 (CN) 201510648429.6

(51) Int. Cl. H01L 51/00; G09G 3/3225; H01L 27/32; H01L 51/56

(52) U.S. Cl. CPC H01L 51/0094; H01L 51/56; H01L 27/3276; G09G 3/3225

(57) ABSTRACT

A silicon-based large-sized OLED image transceiving device comprises an OLED micro-display control and power supply unit, an OLED row driver, an OLED column driver, an image sensor control and power supply unit, an image sensor column signal output unit, a signal processing unit, an image sensor row driver, an OLED display region and a light-sensitive region, each of them is formed on an independent exposure unit or an independent exposure area divided into at least two exposure units, and the device is formed by splicing the exposure units together after exposure.

### CROSS REFERENCE TO RELATED APPLICATIONS

This application is a continuation application of PCT/CN2015/095501, filed on Nov. 25, 2015. The contents of PCT/CN2015/095501 are all hereby incorporated by reference.

### TECHNICAL FIELD

The present invention relates to a silicon-based large-sized OLED image transceiving device and a manufacturing method.

### BACKGROUND ART

An Organic Light Emitting Diode (OLED) has the advantages of high luminance, low driving voltage, quick response, no view limitation, low power consumption, being ultra-light and ultra-thin and shapable in any form, red/green/blue single color or white color output, and long service life, etc., and thus has a huge application prospect in the fields of displays and the like. An OLED image transceiving device combined with a silicon-based CMOS (Complementary Metal-Oxide-Semiconductor Transistor) driver circuit can be integrated with functions such as image display, image pick-up, signal processing and control, and the like.

FIG. 1 shows a shape of micro-display devices 91 distributed on a silicon wafer 90. A typical size of a silicon wafer is 200 mm in diameter. The maximum area of a micro-display is decided by an exposure field, which is generally far less than the area of the silicon wafer. Thus, hundreds of micro-displays can be manufactured on one silicon wafer. The manufacturing method is specifically as follows: a wafer supporting stage of a photoetching machine carries the silicon wafer to each exposure field position for exposure of the micro-display at this position. Then, the silicon wafer is moved step by step to next exposure field position for next exposure, and so forth, until exposure patterns cover all available area of the silicon wafer. Such an exposure method is called stepping exposure. Scribe lines 92 are formed in gaps between these micro-display devices, and micro-display chips are cut off using a scribing blade along the scribe lines at a back-end step and then encapsulated into a micro-display product.

An OLED image transceiving device having an image transceiving function may be integrated with both OLED display function and image sensor function with a photodiode being placed beside and separated from an OLED light-emitting source. In contrast to the traditional OLED micro-display, the OLED image transceiving device has the following major advantages: the display and imaging functions are integrated on the same CMOS chip; external electro-optical components are reduced, and the HMD size is reduced; the system is mare portable, cheaper, stronger in functionality, higher in performance, and low in power consumption; it can be applied to micro-displays, such as a Head-Mounted Display (HMD), a mobile device or a micro-projection device, a Head Up Display (HUD), an electronic viewfinder, etc.; a bidirectional micro-display capable of penetrating display and image pick-up/video recording is achieved, such as interactive HMD, optical inspection, etc.; a sensor, such as an optical sensor, serves to fluorescence, color, flow measurement, etc.

High-resolution, large-area display and imaging can be applied to different fields. At present, the mainstream exposure method is stepping or scanning exposure. With gradually increasing of display screen sizes, the effective exposure area of a stepping exposure machine is limited and the effective region of a mask cannot cover a whole display screen. Consequently, the prior art has difficulties in realizing exposure of above 1.2 inch display screens.

### SUMMARY OF THE INVENTION

The present invention mainly aims at providing a silicon-based large-sized OLED image transceiving device and a manufacturing method with respect to the shortages of the prior art.

To achieve the above purpose, the present invention employs the following technical solutions:

A silicon-based large-sized OLED image transceiving device comprises an OLED micro-display control and power supply unit, an OLED row driver, an OLED column driver, an image sensor control and power supply unit, an image sensor column signal output unit, a signal processing unit, an image sensor row driver, an OLED display region and a light-sensitive region, wherein the light-sensitive region and the OLED display region share an active region of the image transceiving device; the OLED micro-display control and power supply unit is connected to the OLED display region and the light-sensitive region via the OLED row driver and the OLED column driver, respectively; the OLED display region and the light-sensitive region are connected to the image sensor control and power supply unit sequentially via the image sensor column signal output unit and the signal processing unit; and the image sensor control and power supply unit is connected to the OLED display region and the light-sensitive region via the image sensor row driver;

Therein, each of the OLED micro-display control and power supply unit, the OLED row driver, the OLED column driver, the image sensor control and power supply unit, the image sensor column signal output unit, the signal processing unit, the image sensor row driver, the OLED display region and the light-sensitive region is formed on an independent exposure unit or an independent exposure area divided into at least two exposure units, and the device is formed by splicing the exposure units together after exposure.

Further, the OLED row driver and the image sensor row driver are arranged on two transverse sides of the active region of the image transceiving device, respectively, and the OLED column driver and the image sensor column signal output unit are arranged on two longitudinal sides of the active region of the image transceiving device, respectively; and under a condition that a diagonal size of the active region of the image transceiving device is greater than a first size and less than a second size, each of the OLED column driver, the image sensor column signal output unit and the active region of the image transceiving device is longitudinally divided into two exposure units.

Further, the first size is 1.2 inches, and the second size is 2 inches.

Further, the OLED row driver and the image sensor row driver are arranged on two transverse sides of the active region of the image transceiving device, respectively, and the OLED column driver and the image sensor column signal output unit are arranged on two longitudinal sides of the active region of the image transceiving device, respectively, and under a condition that the diagonal size of the active region of the image transceiving device is greater than a second size, each of the OLED column driver, the image sensor column signal output unit and the active region of the image transceiving device is longitudinally divided into two exposure units, and then each of the divided exposure units is transversely divided into two smaller exposure units.

Further, the second size is 2 inches.

Further, the active region of the image transceiving device comprises display row lines, display column lines, image sensing row lines, image sensing column lines, and a pixel matrix composed of pixels. The display row lines and the display column lines are connected to the OLED row driver and the OLED column driver, respectively, and the image sensing row lines and the image sensing column lines are connected to the image sensor row driver and the image sensor column signal output unit, respectively. Preferably, the pixel is square and comprises three subpixels and a light-sensitive unit, with all the subpixels and the light-sensitive unit occupying the symmetrically divided four square regions of the square, respectively, each subpixel being horizontally connected to the corresponding display row line and vertically connected to the corresponding display column line, and the light-sensitive unit being horizontally connected to the image sensor row line and vertically connected to the image sensor column line.

Further, the image transceiving device is a monocrystalline silicon-based CMOS driven OLED image transceiving device.

Further, a length-width ratio of the active region of the image transceiving device is 4:3.

Provided is a manufacturing method for the silicon-based large-sized OLED image transceiving device, wherein each of the OLED micro-display control and power supply unit, the OLED row driver, the OLED column driver, the image sensor control and power supply unit, the image sensor column signal output unit, the signal processing unit, the image sensor row driver, the OLED display region and the light-sensitive region in the image transceiving device is formed on an independent exposure unit or an independent exposure area divided into at least two exposure units, and the device is formed by splicing the exposure units together after exposure. During the exposure process, each exposure unit is within the range of one light field of an exposure system and each exposure unit is sequentially exposed with a respective mask, wherein the image transceiving device is moved to an exposure position for next exposure unit for exposure after the exposure of one exposure unit is finished; thus, different exposure regions are exposed with different mask. Finally, the manufacturing of the whole image transceiving device can be completed by splicing the exposure regions.

Further, the exposure system is a stepping exposure system.

The present invention can provide a high-resolution, silicon-based large-sized OLED image transceiving device, which is based on different exposure units and formed by splicing after exposure. As a result, the problem of difficult exposure of above 1.2 inch display screens in the prior art is overcome. With the manufacturing method of the present invention, the high-resolution, silicon-based large-sized OLED image transceiving device can be achieved simply and effectively through reasonable unit division, layout design and exposure field splicing.

### BRIEF DESCRIPTION OF THE DRAWINGS

FIG. 1 illustrates a shape of an existing OLED image transceiving device.

FIG. 2 illustrates building blocks of a silicon-based large-sized OLED display device of embodiment 1 of the present invention.

FIG. 3 illustrates a layout of an active display region of an OLED image transceiving device of embodiment 1 of the present invention.

FIG. 4 illustrates a layout of subpixels of embodiment 1 of the present invention.

FIG. 5 illustrates schematic cross-section diagram of an OLED image transceiving device of embodiment 1 and embodiment 2 of the present invention.

FIG. 6 illustrates exposure units of the OLED image transceiving device of embodiment 1 of the present invention.

FIG. 7 illustrates exposure units of the OLED image transceiving device of embodiment 2 of the present invention.

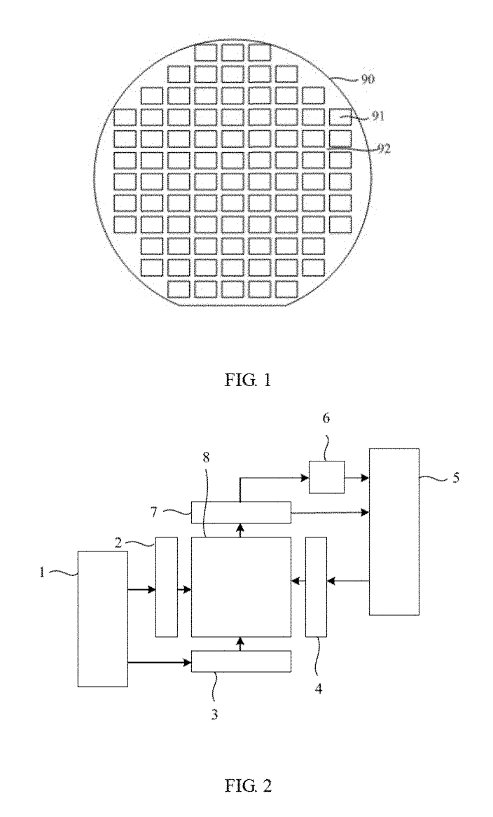

### DETAILED DESCRIPTION

Embodiments of the present invention will be described in detail below. It should be emphasized that the following descriptions are merely illustrative and not intended to limit the scope of the present invention and uses thereof.

Referring to FIG. 2, in an embodiment, a silicon-based large-sized OLED image transceiving device comprises an OLED micro-display control and power supply unit 1, an OLED row driver 2, an OLED column driver 3, an image sensor control and power supply unit 5, an image sensor column signal output unit 7, a signal processing unit 6, an image sensor row driver 4, an OLED display region, and a light-sensitive region 8. Therein, the light-sensitive region and the OLED display region 9 share an active region of the image transceiving device. The OLED micro-display control and power supply unit 1 is connected to the OLED display region and the light-sensitive region 8 via the OLED row driver 2 and the OLED column driver 3, respectively. The OLED display region and the light-sensitive region 8 are connected to the image sensor control and power supply unit 5 sequentially via the image sensor column signal output unit 7 and the signal processing unit 6. The image sensor control and power supply unit 5 is connected to the OLED display region and the light-sensitive region 8 via the image sensor row driver 4. Therein, each of the OLED micro-display control and power supply unit 1, the OLED row driver 2, the OLED column driver 3, the image sensor control and power supply unit 5, the image sensor column signal output unit 7, the signal processing unit 6, the image sensor row driver 4, the OLED display region and the light-sensitive region 8 is formed on an independent exposure unit or an independent exposure area divided into at least two exposure units, and the device is formed by splicing the exposure units together after exposure.

In a preferred embodiment, the OLED row driver 2 and the image sensor row driver 4 are arranged on two transverse sides of the active region of the image transceiving device, respectively, and the OLED column driver 3 and the image sensor column signal output unit 7 are arranged on two longitudinal sides of the active region of the image transceiving device, respectively. Under a condition that a diagonal size of the active region of the image transceiving device is greater than a first size and less than a second size, each of the OLED column driver 3, the image sensor column signal output unit 7 and the active region of the image transceiving device is longitudinally divided into two exposure units. More preferably, the first size is 1.2 inches and the second size is 2 inches.

In a preferred embodiment, the OLED row driver 2 and the image sensor row driver 4 are arranged on two transverse sides of the active region of the image transceiving device, respectively, and the OLED column driver 3 and the image sensor column signal output unit 7 are arranged on two longitudinal sides of the active region of the image transceiving device, respectively. Under a condition that a diagonal size of the active region of the image transceiving device is greater than a first size and less than a second size, each of the OLED column driver 3, the image sensor column signal output unit 7 and the active region of the image transceiving device is longitudinally divided into two exposure units. More preferably, the second size is 2 inches.

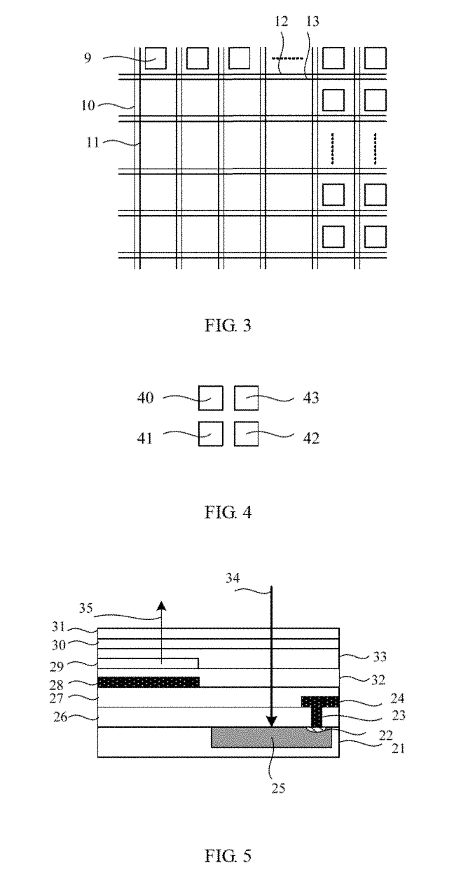

As shown in FIG. 3 to FIG. 4, in a preferred embodiment, the active region of the image transceiving device comprises display row lines 12, display column lines 10, image sensing row lines 13, image sensing column lines 11, and a pixel matrix composed of pixels 9. The display row lines and the display column lines are connected to the OLED row driver 2 and the OLED column driver 3, respectively, and the image sensing row lines and the image sensing column lines are connected to the image sensor row driver 4 and the image sensor column signal output unit 7, respectively. More preferably, the pixel is square and comprises three subpixels 40, 41, 43 and a light-sensitive unit 42, with these subpixels and the light-sensitive unit 42 occupying the symmetrically divided four square regions of the square, respectively, each subpixel being horizontally connected to the corresponding display row line 12 and vertically connected to the corresponding display column line 10, and the light-sensitive unit 42 being horizontally connected to the image sensor row line 13 and vertically connected to the image sensor column line 11.

In some embodiments, a length-width ratio of the active region of the image transceiving device is 4:3.

In some embodiments, the image transceiving device is a monocrystalline silicon-based CMOS driven OLED image transceiving device.

In another embodiment, there is provided a manufacturing method for the silicon-based large-sized OLED image transceiving device. According to this method, each of the OLED micro-display control and power supply unit, the OLED row driver 2, the OLED column driver 3, the image sensor control and power supply unit 5, the image sensor column signal output unit 7, the signal processing unit 6, the image sensor row driver 4, the OLED display region and the light-sensitive region 8 in the image transceiving device is formed on an independent exposure unit or an independent exposure area divided into at least two exposure units, and the device is formed by splicing the exposure units together after exposure. During the exposure process, each exposure unit is within the range of one light field of an exposure system and each exposure unit is sequentially exposed with a respective mask (not shown in the figure), where the image transceiving device is moved to an exposure position for next exposure unit for exposure after the exposure of one exposure unit is finished. Thus, different exposure regions are exposed with different masks, and finally, the manufacturing of the whole image transceiving device can be completed by splicing the exposure regions.

In a preferred embodiment, the exposure system is a stepping exposure system.

In some specific embodiments, the active region of the OLED image transceiving device comprises a pixel matrix, with each pixel including three light-emitting subpixels and a light-sensitive unit. A typical length-width ratio of the active region of the image transceiving device is 4:3 with the diagonal size thereof being greater than 1.2 inches, and the image transceiving device is divided into a number of exposure units. If the diagonal size of the active region of the image transceiving device is less than 2 inches, one longitudinal division is employed. If the diagonal size of the active region of the image transceiving device is greater than 2 inches, one longitudinal division and one transverse division are employed.

In some specific embodiments, the image transceiving device is formed by the method of exposure and splicing, where each of the divided exposure units is within the range of one light field of a stepping exposure system, and the exposure units are exposed with different masks, respectively, and then moved step by step to next positions for secondary exposure. Thus, different exposure regions are exposed with different masks, and then are spliced by using an alignment system of the exposure system, and finally, the manufacturing of the whole image transceiving device can be completed.

### Embodiment 1

FIG. 2 is a schematic diagram of a large-sized OLED image transceiving device of this embodiment 1. This embodiment provides a CMOS driven OLED image transceiving device comprising an OLED micro-display control and power supply unit 1, the OLED row driver 2, the OLED column driver 3, the image sensor control and power supply unit 5, the image sensor column signal output unit 7, the signal processing unit 6, the image sensor row driver 4, the OLED display region and the light-sensitive region 8, wherein the light-sensitive region and the OLED display region 8 share an active region of the image transceiving device.

The OLED micro-display control and power supply unit 1 controls the OLED row and column drivers. The OLED row driver 2 outputs a row scanning pulse for addressing a light-emitting pixel of the OLED. A digital signal is transmitted to the OLED column driver by the OLED display control unit and sent to each column of the OLED display region.

The image sensor control unit 5 controls the image sensor row driver 4 to address each row of an image sensor. A light-sensitive signal in each column is output to the signal processing unit 6 from the image sensor column signal output unit 7 and a processed video signal is sent to the image sensor control unit 5.

The active region of the image transceiving device includes the OLED display region and the light-sensitive region of the image sensor. With reference to FIG. 3, the active region includes a pixel matrix, has a typical length-width ratio being 4:3 and a diagonal size being greater than 1.2 inches, and comprises display row lines 12, display column lines 10, image sensing row lines 13, image sensing column lines 11, and a pixel matrix composed of pixels 9. The display row lines and column lines are connected to a display row driver and a display column driver, respectively, and the image sensing row lines and the image sensing column lines are connected to the image sensor row driver 4 and the image sensor column signal output unit 7, respectively.

Referring to FIG. 4, the pixel 9 is designed to be square. The pixel 9 comprises a subpixel 40, a subpixel 41, a subpixel 43, and a light-sensitive unit 42. Each subpixel occupies one position that is interchangeable, and all the subpixels are designed to be square. The display subpixels are horizontally connected to corresponding display row scanning lines and vertically connected to corresponding display column data lines, respectively, and the light-sensitive unit is horizontally connected to an image sensor row addressing line and vertically connected to an image sensor column signal output line.

FIG. 5 is a schematic cross-section diagram of one light-emitting subpixel and the light-sensitive unit in a pixel 9 of the OLED image transceiving device of the embodiment 1. This embodiment provides an OLED image transceiving device integrated with a photodiode as a light-sensitive unit. This device comprises a silicon substrate, a photodiode, and an OLED.

An n-well 25 is formed in a p-Si substrate 21, and the p-Si substrate 21 and the n-well 25 form the photodiode. An interlayer insulating barrier 26 is continuously formed and a plug 23 is formed in the interlayer insulating barrier 26. The n-well 25 is connected with a contact 22 and connected to a metal interconnection line 24 formed on the interlayer insulating barrier by means of the plug 23. An intermetallic insulating barrier 27 is formed on the interlayer insulating barrier 26 and the metal interconnection line 24. A metal interconnection line 28 is formed on the intermetallic insulating barrier 27 and connected to a drain electrode (not shown in the figure) of a field-effect transistor by means of a plug. The metal interconnection line 28 serves as a reflecting anode of the OLED.

The OLED comprises the metal interconnection line 28, organic layers 29, and a transparent cathode 30. The metal interconnection line 28 may be made of silver, gold, chromium, aluminum, copper, molybdenum, tantalum, tungsten, etc., or various alloys formed by such materials. Various organic layers 29 are sequentially formed on the anode 28, and a transparent conducting layer 30 is formed on the organic layers 29. The transparent conducting layer may be a transparent conducting film like ITO, IZO, and may also be a transparent conducting layer formed by a thin metal film. A thin film encapsulation layer 31 is formed on the transparent cathode 30 to protect the OLED below.

After a voltage is applied to both anode and cathode of the OLED, light is emitted from the organic layers 29, and part of the light becomes outward output light 35, while incident light 34 is unblocked and can be detected by the photodiode.

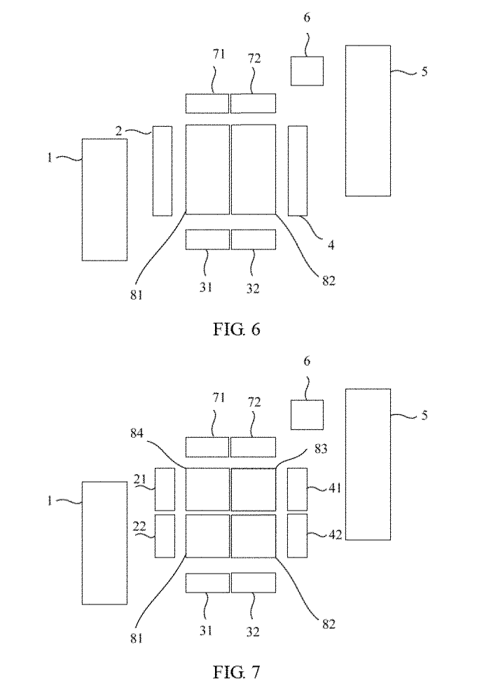

The diagonal size of the active region of the image transceiving device may be greater than 1.2 inches, and the exposure cannot be completed in one exposure field in an existing exposure manner. Therefore, the image transceiving device is divided into a number of exposure units. Referring to FIG. 6, in this embodiment, the diagonal size of the active region of the image transceiving device is less than 2 inches, one longitudinal division is employed. The exposure units include an OLED micro-display control and power supply unit 1, an OLED row driver 2, an image sensor control and power supply unit 5, a signal processing unit 6, and an image sensor row driver 4. An OLED column driver is divided into two units, which are an OLED column driver 31 and an OLED column driver 32, respectively. An image sensor column signal output unit is divided into two units, which are an image sensor column signal output unit 71 and an image sensor column signal output unit 72, respectively. An active region of the image transceiving device is divided into active region 81 of the image transceiving device and active region 82 of the image transceiving device.

The image transceiving device is formed by the method of exposure and splicing. Each unit is within the range of one light field of an exposure system, and in a specific implementation process, the OLED micro-display control and power supply unit 1 is exposed with one mask. Next, a silicon slice is moved step by step to the exposure position of the OLED row driver 2 for secondary exposure with another mask. Then, silicon slice is moved step by step to the exposure position of the active region 81 of the image transceiving device for third exposure with another mask. Thus, different exposure regions are exposed with different masks, and then are spliced by using an alignment system of the exposure system, and finally, the manufacturing of the whole image transceiving device can be completed.

This example may allow for formation of a 1.2 to 2 inch image transceiving device.

### Embodiment 2

In this embodiment, the diagonal size of the active region of the image transceiving device may be greater than 2 inches, and the exposure cannot be completed in one exposure field in an existing exposure manner. Therefore, the image transceiving device is divided into a number of exposure units. Referring to FIG. 7, unlike the embodiment 1, the diagonal size of the active region of the image transceiving device may be greater than 2 inches in this embodiment, and one longitudinal division and one transverse division are employed. The exposure units include an OLED micro-display control and power supply unit 1, an OLED row driver that is divided into an OLED row driver 21 and an OLED row driver 22, an image sensor control and power supply unit 5, a signal processing unit 6, and an image sensor row driver 4 that is divided into an image sensor row driver 41 and an image sensor row driver 42. An OLED column driver is divided into two units, which are an OLED column driver 31 and an OLED column driver 32, respectively. An image sensor column signal output unit is divided into two units, which are an image sensor column signal output unit 71 and an image sensor column signal output unit 72, respectively. An active region of the image transceiving device is divided into active region 81 of the image transceiving device, active region 82 of the image transceiving device, active region 83 of the image transceiving device, and active region 84 of the image transceiving device.

The image transceiving device is formed by the method of exposure and splicing. Each unit is within the range of one light field of an exposure system, and in a specific implementation process, the OLED micro-display control and power supply unit 1 is exposed with one mask. Next, a silicon slice is moved step by step to the exposure position of the OLED row driver 2 for secondary exposure and third exposure with another mask. Then, the silicon wafer is moved step by step to the exposure position of the active region 8 of the image transceiving device for third, fourth, fifth and sixth exposures, thereby forming the active region 81 of the image transceiving device, the active region 82 of the image transceiving device, the active region 83 of the image transceiving device, and the active region 84 of the image transceiving device, respectively. Thus, different exposure regions are exposed with different masks, and then are spliced by using an alignment system of the exposure system, and finally, the manufacturing of the whole image transceiving device can be completed.

This example may allow for formation of 1.2 to 2 inch, and even above 2 inch image transceiving devices.

The foregoing are further detailed descriptions of the present invention in conjunction with specific/preferred embodiments and the specific embodiments of the present invention cannot be regarded as being restricted to these descriptions. For those skilled in the art, various substitutions or variations can also be made to these described embodiments without departing from the concept of the present invention, and these substitutions or variations shall be deemed to fall into the scope of protection of the present invention.

1. A silicon-based large-sized OLED image transceiving device, comprising an OLED micro-display control and power supply unit, an OLED row driver, an OLED column driver, an image sensor control and power supply unit, an image sensor column signal output unit, a signal processing unit, an image sensor row driver, an OLED display region and a light-sensitive region, wherein the light-sensitive region and the OLED display region share an active region of the image transceiving device the OLED micro-display control and power supply unit is connected to the OLED display region and the light-sensitive region via the OLED row driver and the OLED column driver, respectively; the OLED display region and the light-sensitive region are connected to the image sensor control and power supply unit sequentially via the image sensor column signal output unit and the signal processing unit; the image sensor control and power supply unit is connected to the OLED display region and the light-sensitive region via the image sensor row driver;
wherein each of the OLED micro-display control and power supply unit, the OLED row driver, the OLED column driver, the image sensor control and power supply unit, the image sensor column signal output unit, the signal processing unit, the image sensor row driver, the OLED display region and the light-sensitive region is formed on an independent exposure unit or an independent exposure area divided into at least two exposure units, and the device is formed by splicing the exposure units together after exposure.

2. The silicon-based large-sized OLED image transceiving device according to claim 1, wherein the OLED row driver and the image sensor row driver are arranged on two transverse sides of the active region of the image transceiving device, respectively, and the OLED column driver and the image sensor column signal output unit are arranged on two longitudinal sides of the active region of the image transceiving device, respectively; and under a condition that a diagonal size of the active region of the image transceiving device is greater than a first size and less than a second size, each of the OLED column driver, the image sensor column signal output unit and the active region of the image transceiving device is longitudinally divided into two exposure units.

3. The silicon-based large-sized OLED image transceiving device according to claim 2, wherein the first size is 1.2 inches, and the second size is 2 inches.

4. The silicon-based large-sized OLED image transceiving device according to claim 1, wherein the OLED row driver and the image sensor row driver are arranged on two transverse sides of the active region of the image transceiving device, respectively, and the OLED column driver and the image sensor column signal output unit are arranged on two longitudinal sides of the active region of the image transceiving device, respectively; and under a condition that the diagonal size of the active region of the image transceiving device is greater than a second size, each of the OLED column driver, the image sensor column signal output unit and the active region of the image transceiving device is longitudinally divided into two exposure units, and then each of the divided exposure units is transversely divided into two smaller exposure units.

5. The silicon-based large-sized OLED image transceiving device according to claim 4, wherein the second size is 2 inches.

6. The silicon-based large-sized OLED image transceiving device according to claim 1, wherein the active region of the image transceiving device comprises display row lines, display column lines, image sensing row lines, image sensing column lines, and a pixel matrix composed of pixels; the display row lines and the display column lines are connected to the OLED row driver and the OLED column driver, respectively, and the image sensing row lines and the image sensing column lines are connected to the image sensor row driver and the image sensor column signal output unit, respectively; and preferably, the pixel is square and comprises three subpixels and a light-sensitive unit, with all the subpixels and the light-sensitive unit occupying the symmetrically divided four square regions of the square, respectively, each subpixel being horizontally connected to the corresponding display row line and vertically connected to the corresponding display column line, and the light-sensitive unit being horizontally connected to the image sensor row line and vertically connected to the image sensor column line.

7. The silicon-based large-sized OLED image transceiving device according to claim 1, wherein the image transceiving device is a monocrystalline silicon-based CMOS driven OLED image transceiving device.

8. The silicon-based large-sized OLED image transceiving device according to claim 1, wherein a length-width ratio of the active region of the image transceiving device is 4:3.

9. A manufacturing method for the silicon-based large-sized OLED image transceiving device according to claim 1, wherein each of the OLED micro-display control and power supply unit, the OLED row driver, the OLED column driver, the image sensor control and power supply unit, the image sensor column signal output unit, the signal processing unit, the image sensor row driver, the OLED display region and the light-sensitive region in the image transceiving device is formed on an independent exposure unit or an independent exposure area divided into at least two exposure units, and the device is formed by splicing the exposure units together after exposure; during the exposure process, each exposure unit is within the range of one light field of an exposure system and each exposure unit is sequentially exposed with a respective mask, wherein the image transceiving device is moved to an exposure position for next exposure unit for exposure after the exposure of one exposure unit is finished; thus, different exposure regions are exposed with different masks, and finally, the manufacturing of the whole image transceiving device can be completed by splicing the exposure regions.

10. The manufacturing method for the silicon-based large-sized OLED image transceiving device according to claim 9, wherein the exposure system is a stepping exposure system.
